(19) United States
(12) Patent Application Publication
(10) Pub. No.: US 2005/0207119 A1
(43) Pub. Date: Sep. 22, 2005

(54) Heat dissipation module of an interface card

(76) Inventor: Ming Tang Huang, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/801,702

(22) Filed: Mar. 17, 2004

(51) Int. Cl. H05K 7/20

(52) U.S. Cl. 361/697; 165/120

(57) ABSTRACT

The heat dissipation module has a heat sink and at least one hooking device. The heat sink has a base abutting an electrical component of the interface card, a plurality of fins outwardly extending from each side of the base and at least one holding portion having a connecting arm outwardly extending from a side of the base, two symmetrical retaining arm respectively outwardly extending from an end of the connecting arm and a receiving space defined by the two retaining arm. The at least one hooking device is received in the receiving space of the at least one holding portion for hooking the heat sink on the interface card.

### BACKGROUND OF THE INVENTION

(1) Field of the Invention

The present invention relates to a heat dissipation module of an interface card. More particularly, after adding a heat dissipation area to a heat sink of the heat dissipation module, the heat sink does not interfere with electrical components on the interface card.

(2) Description of the Related Art

Recently, shapes of electrical products become smaller and have various functions. Heat dissipation problems of electrical components in the electrical products consequently are more critical.

Referring to FIGS. 1-3, a conventional heat dissipation module 1a of a interface card 30a has a heat sink 10a and two hooking devices 20a mounted on the heat sink 10a for hooking the heat sink 10a on the interface card 30a. The heat sink 10a is made by aluminum extrusion. The heat sink 10a has a base 100a and a plurality of fins 110a upwardly extending from a top of the base 100a. The base 100a has two through holes 102a defined therein. The interface card 30a has two holes 302a respectively corresponding to the two through holes 102a of the base 100a. Each of the two hooking devices 20a has a member sleeve 200a, a spring 220a and a hooking member 240a. The spring 220a is compressedly received in the member sleeve 200a. The hooking member 240a is inserted into the spring 220a and an opening of a bottom of the member sleeve 200a, for hooking the heat sink 10a on the interface card 30a. Each of the two hooking member 240a has a hooking member body 2402a, a retaining portion 2404a and two hooks 2406a. The retaining portion 2404a outwardly protrudes from a top of the hooking member body 2402a. Two hooks 2406a are symmetrically formed on a bottom of the hooking member body 2402a.

The heat sink 10a is mounted on a heating electrical component 304a of the interface card 30a, and the two through holes 102a of the base 100a are respectively aimed at two holes 302a of the interface card 30a. The two hooking devices 20a respectively correspond with the two through holes 102a of the base 100a. Each hooking member 240a of the hooking device 20a is pressed down. The springs 220a are pressed by the retaining portion 2404 of the hooking member 240a, and the two hooks 2406a pass through the two holes 302a of the interface card 30a. An external force deforms the two hooks 2406a of the hooking member 240a inwardly. When the external force is removed, the two hooks 2406a of the hooking member 240a respectively return to their original forms and then the heat sink 10a is hooked on the interface card 30a.

Consequently, the base 100a of the heat sink 10a abuts the heating electrical component 304a of the interface card 30a. Heat from the electrical component 304a is transmitted to the fins 110a of the heat sink 10a. Heat convection of the fins 110a and the air dissipate the heat from the electrical component 304a to prevent the interface card 30a from overheating.

The heat sink 10a that meets a demanded heat dissipation area is cut from an aluminum strip. The aluminum strip has a base and a plurality of fins respectively extending from a top of the base. The aluminum strip is made by extruding a heated aluminum ingot in an extruding die.

However, after testing, a heat sink 10a with a poor heat dissipation efficiency may be detected. Such a deficient heat sink 10a would affect the stability of the interface card 30a and thus necessitates the addition of a heat dissipation area to the heat sink 10a to improve the heat dissipation efficiency thereof.

Referring to FIG. 3, the height of the fin 110a cannot added to without making a new extruding die. The only way is to add to the length of the fin 100a transversely to increase the heat dissipation area in order to improve heat dissipation efficiency. Nevertheless, the heat sink 10a with added length interferes with a peripheral electrical component 306a easily and requires redesign of the interface card 30a layouts, which wastes a lot of time and adds costs. Besides, the heat sink 10a with added length occupies a larger area of the printed circuit board and affects placement of the peripheral electrical components, making design of the interface card more difficult.

Furthermore, after pressing the hooking member 240a, the hooking devices 20a sways easily so that the through hole 102a of the base 100a does not correspond with the hole 302a of the interface card 30a.

According to above descriptions, the conventional heat dissipation module 1a still has some issues that need to be improved.

### SUMMARY OF THE INVENTION

The object of the present invention is to provide a heat dissipation module of an interface card; after adding heat dissipation area of a heat sink of the heat dissipation module, the heat sink does not interfere with electrical components on an interface card.

In order to achieve the above object, the present invention provides a heat dissipation module of an interface card. The heat dissipation module has a heat sink and at least one hooking device. The heat sink has a base abutting an electrical component of the interface card, a plurality of fins outwardly extending from each side of the base and at least one holding portion having a connecting arm outwardly extending from a side of the base, two symmetrical retaining arm respectively outwardly extending from an end of the connecting arm and a receiving space defined by the two retaining arm. The at least one hooking device is received in the receiving space of the at least one holding portion for hooking the heat sink on the interface card.

So as to avoid making a new extruding die, height of the fin can be vertically added to by adding a heat dissipation area for improving heat dissipation efficiency. Consequently, the heat sink with added height does not interfere with a peripheral electrical component and does not require that the interface card be laid out again, which save a lot of time and cost. Additionally, the heat sink with added height does not occupy a printed circuit board area further and does not affect the peripheral electrical component, so that design thereof is more flexible.

It is to be understood that both the foregoing general description and the following detailed description are exemplary, and are intended to provide further explanation of the invention as claimed.

Other advantages and features of the invention will be apparent from the following description, drawings and claims.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a perspective view of a conventional heat dissipation module of an interface card;

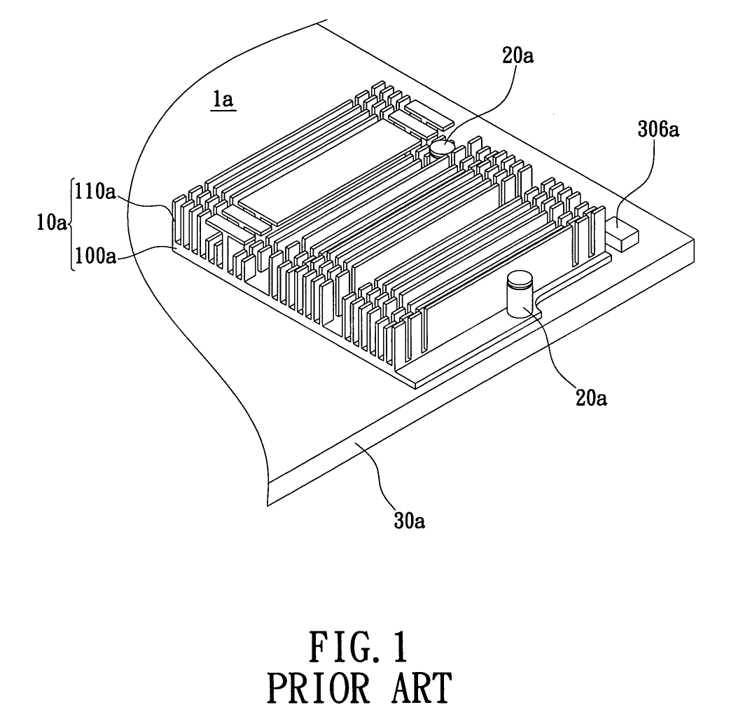

FIG. 2 is an exploded view of the conventional heat dissipation module of the interface card;

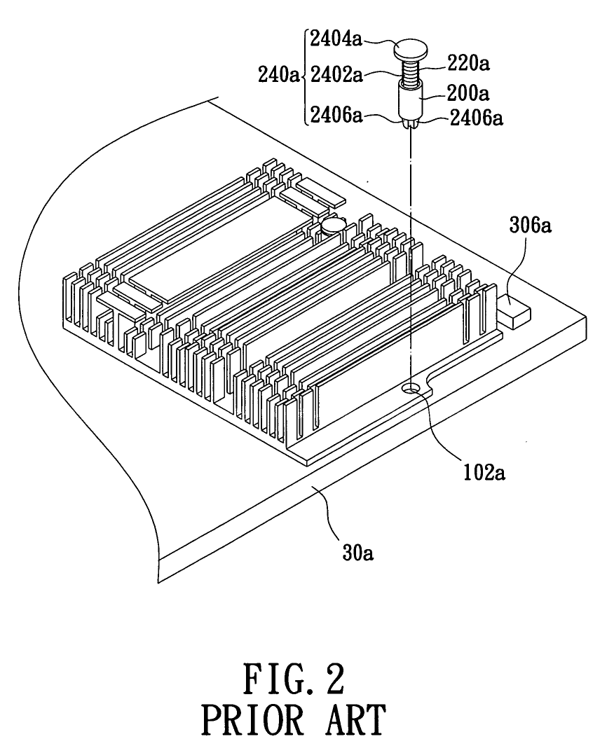

FIG. 3 is a side view of the conventional heat dissipation module of the interface card;

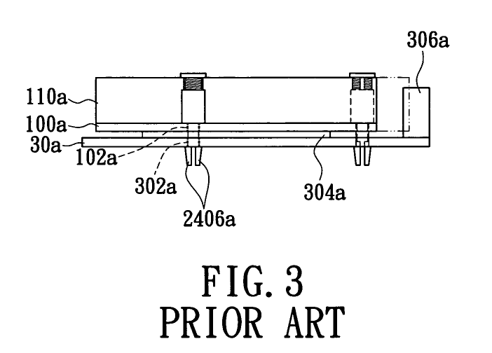

FIG. 4 is a perspective view of a heat dissipation module of an interface card in accordance with the present invention;

FIG. 5 is an exploded view of the heat dissipation module of the interface card in accordance with the present invention;

FIG. 6 is a top view of the heat dissipation module of the interface card in accordance with the present invention; and

FIG. 7 is a perspective view showing a fan mounted on the heat dissipation module of the interface card in accordance with the present invention.

### DETAILED DESCRIPTION OF PREFERRED EMBODIMENTS

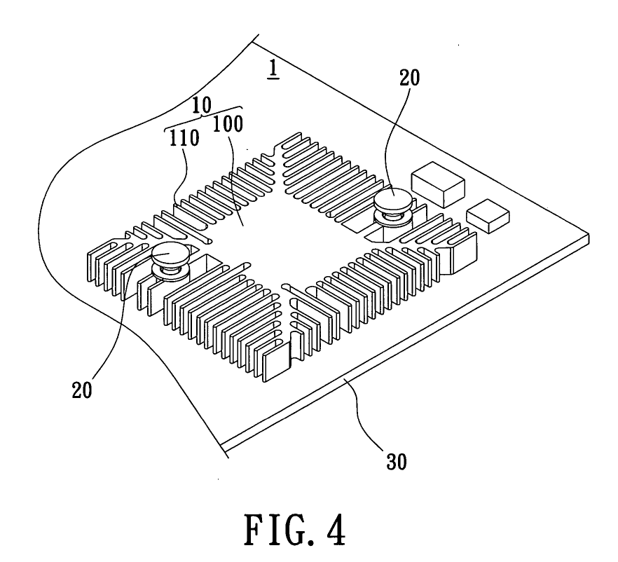

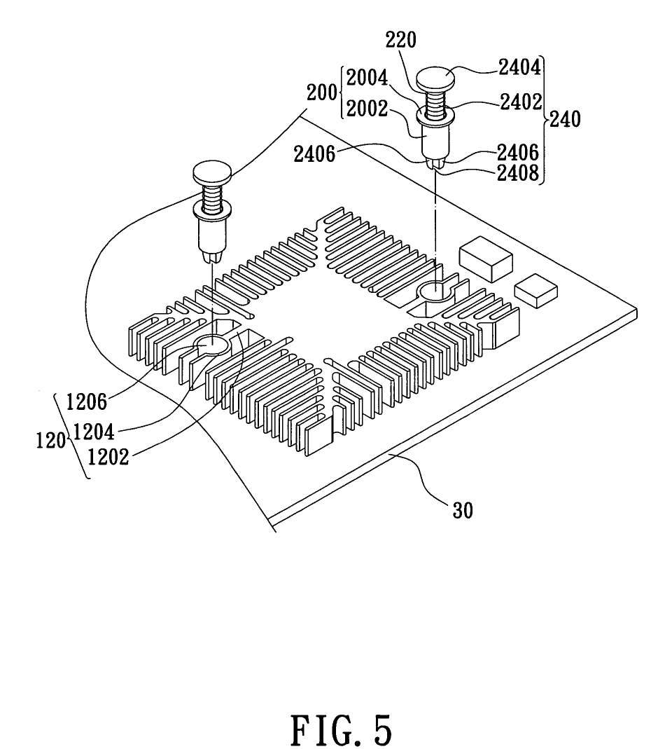

Referring to FIG. 4-6, a heat dissipation module 1 of an interface card 30 has a heat sink 10 and two hooking devices 20 for hooking the heat sink 10 on the interface card 30.

The heat sink 10 is made by aluminum extrusion. The heat sink 10 has a base 100, a plurality of fins 110 and two holding portions 120. The base 100 abuts an electrical component of the interface card. The fins 110 outwardly extend from each side of the base 100. Each of the two holding portions 120 has a connecting arm 1202, two symmetrical retaining arm 1204 and a receiving space 1206; the connecting arm 1202 outwardly extends from a side of the base 100, the two symmetrical retaining arm 1204 respectively outwardly extend from an end of the connecting arm 1202, and the receiving space 1206 is defined by the two retaining arm 1204.

The interface card 30 has two holes 302, which respectively correspond with the two receiving space 1206 of the two holding portions 120. The two holes 302 are defined in the interface card 30.

The two hooking devices 20 are respectively received in the two receiving spaces 1206 of the two holding portions 120 of the heat sink 10 for hooking the heat sink 10 on the interface card.

Each of the two hooking devices 20 has a member sleeve 200, a spring 220 and a hooking member 240. The member sleeve 200 has a sleeve body 2002 and a circular portion 2004 outwardly protruding along a rim of a top of the sleeve body 2002. The spring 220 is compressedly received in the of the sleeve body 2002 of the member sleeve 200. The hooking member 240 is inserted into the spring 220 and an opening of a bottom of the sleeve body 2002 for hooking the heat sink 10 on the interface card. The hooking member 240 has a hooking member body 2402, a retaining portion 2404, two hooks 2406 and a notch 2408. The retaining portion 2404 outwardly protrudes along a rim of a top of the hooking member body 2402. Two hooks 2406 are symmetrically formed to a bottom of the hooking member body 2402. The notch 2408 is defined by the two hooks 2406.

The heat sink 10 is mounted on a heating electrical component 304 of the interface card 30 and the two receiving spaces 1206 of the two holding portions 120 of the heat sink 10 are respectively aimed at two holes 302 of the interface card 30. The two hooking devices 20 are respectively arranged in the two receiving spaces 1206 of the two holding portions 120 of the heat sink 10. The hooking member 240 of the hooking device 20 is pressed down. The spring 220 is pressed by the retaining portion 2404 of the hooking member 240, and the two hooks 2406 pass through the two holes 302 of the interface card 30. An external force deforms the two hooks 2406 of the hooking member 240 inwardly. When the external force is removed, the two hooks 2406 of the hooking member 240 respectively return to their original forms and then the heat sink 10 is hooked on the interface card 30.

Consequently, the base 100 of the heat sink 10 abuts against the heating electrical component 304 of the interface card 30. Heat from the electrical component 304 is transmitted to the fins 110 of the heat sink 10. Heat convection of the fins 110 and the air dissipate the heat from the electrical component 304 and prevent the interface card 30 from overheating.

The heat sink 10 that meets a required heat dissipation area is cut from an aluminum strip. The aluminum strip has a base and a plurality of fins respectively extending from each side of the base. The aluminum strip is made by extruding a heated aluminum ingot in an extruding die.

After an engineer tests the interface card 30, a heat sink 10 with a poor heat dissipation efficiency, which would affect the stability of the interface card 30, may be detected. For this reason, the heat dissipation area of the heat sink 10 needs to be added in order to improve heat dissipation efficiency of the heat sink 10.

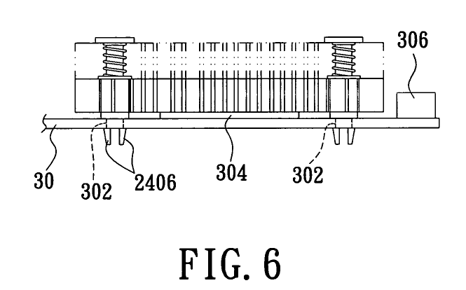

Referring to FIG. 6, although length of the fin 110 cannot be added to without making a new extruding die, the height of the fin 110 can be vertically added to so as to add heat dissipation area and the improve heat dissipation efficiency thereof. Consequently, the heat sink 10 with added height does not interfere with a peripheral electrical component 306 and does not require redesign of the interface card 30 layouts, which save a lot of time and cost. Additionally, the heat sink 10 with added height does not occupy a printed circuit board area further and does not affect the peripheral electrical component 306, so that design thereof is more flexible.

Additionally, each of the two member sleeves 200 has a circular portion 2004 outwardly protruding along a rim of a top of the sleeve body 2002; the two circular portion 2004 of the two member sleeves 200 respectively abut the two retaining arms 1204 of the two holding portions 120, so that the two hooking devices 20 can be securely retained on the heat sink 10 after the two hooking member 240 are pressed. Furthermore, the two receiving spaces 1206 of the two holding portions 120 of the heat sink 10 are kept in correspondence with the two holes 302 of the interface card 30.

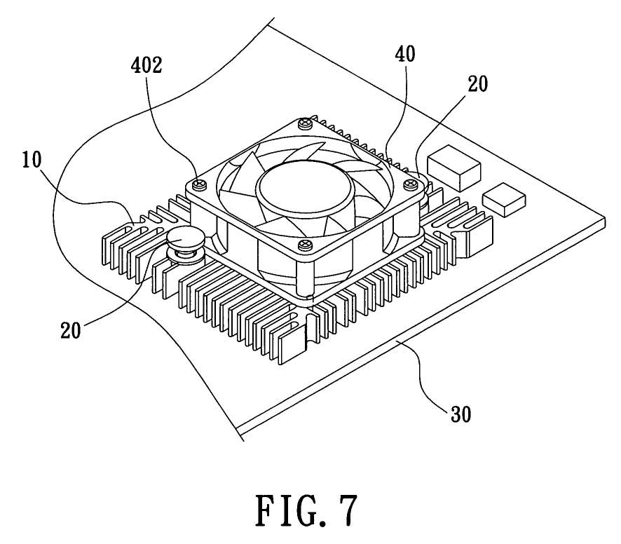

Referring to FIG. 7, the present invention can further has a fan 40 mounted on the heat sink 10 by four screws 402, for providing air to cool the heat sink 10.

According to above description, the present invention has the following advantages:
(1) To avoid making a new extruding die, height of the fin 110 can be vertically extended to add a heat dissipation area, for improving the heat dissipation efficiency thereof. Consequently, the heat sink 10 with added height does not interfere with a peripheral electrical component 306 and does not require layout of the interface card 30 again, which save a lot of time and cost. Additionally, the heat sink 10 with added height does not occupy a printed circuit board area further and does not affect the peripheral electrical component 306, making design thereof more flexible.
(2) The two circular portion 2004 of the two member sleeves 200 respectively abut the two retaining arms 1204 of the two holding portions 120, so that the two hooking devices 20 can be securely retained on the heat sink 10 after the two hooking member 240 are pressed. Furthermore, the two receiving spaces 1206 of the two holding portions 120 of the heat sink 10 are respectively kept in correspondence with the two holes 302 of the interface card 30.
(3) The present invention can further has a fan 40 mounted on the heat sink 10 by four screw 402, for providing air to cool the heat sink 10.

Therefore, the foregoing is considered as illustrative only of the principles of the invention. Further, since in the art, it is not desired to limit the invention to the exact construction and operation shown and described, and accordingly, all suitable modifications and equivalents may be resorted to, falling within the scope of the invention.

1. A heat dissipation module of an interface card, the heat dissipation module comprising:
a heat sink having a base abutting an electrical component of the interface card, a plurality of fins outwardly extending from each side of the base, at least one holding portion having a connecting arm outwardly extending from a side of the base, two symmetrical retaining arm respectively outwardly extending from an end of the connecting arm and a receiving space defined by the two retaining arm; and
at least one hooking device received in the receiving space of the at least one holding portion for hooking the heat sink on the interface card.

2. The heat dissipation module of the interface card as claimed in claim 1, wherein the heat sink is made by aluminum extrusion.

3. The heat dissipation module of the interface card as claimed in claim 1, wherein the at least one hooking device has a member sleeve having a sleeve body and a circular portion outwardly protruding along a rim of a top of the sleeve body, a spring compressedly received in the sleeve body of the member sleeve, and a hooking member inserted into the spring and an opening of a bottom of the sleeve body for hooking the heat sink on the interface card.

4. The heat dissipation module of the interface card as claimed in claim 3, wherein the hooking member has a hooking member body, a retaining portion outwardly protruding along a rim of a top of the hooking member body, two hooks symmetrically formed on a bottom of the hooking member body, and a notch defined by the two hooks.

5. The heat dissipation module of the interface card as claimed in claim 1, further comprising a fan mounted on the heat sink for providing air to cool the heat sink.

6. A heat sink of a heat dissipation module of an interface card, the heat sink comprising:
a base abutting an electrical component of the interface card, and a plurality of fins outwardly extending from each side of the base.

7. The heat sink of the heat dissipation module of the interface card as claimed in claim 6, wherein the heat sink is made by aluminum extrusion.

8. The heat sink of the heat dissipation module of the interface card as claimed in claim 7, further comprising at least one holding portion outwardly extending from a side of the base.

9. The heat sink of the heat dissipation module of the interface card as claimed in claim 8, wherein the at least one holding portion has a connecting arm outwardly extending from the side of the base, two symmetrical retaining arm respectively outwardly extending from an end of the connecting arm and a receiving space defined by the two retaining arm.
